(19) United States
(12) Patent Application Publication
(10) Pub. No.: US 2024/0337017 A1
(43) Pub. Date: Oct. 10, 2024

(54) ANTI-DEPOSITION OBJECT

(71) Applicant: HIGHLIGHT TECH CORP., Tainan City (TW)

(72) Inventors: CHIEN-HSUN CHEN, Tainan City (TW); SHIH-YUAN SUN, Tainan City (TW); MIN-JUI WU, Tainan City (TW); CHIH-CHIANG FANG, Tainan City (TW)

(73) Assignee: HIGHLIGHT TECH CORP., Tainan City (TW)

(21) Appl. No.: 18/406,000

(22) Filed: Jan. 5, 2024

Related U.S. Application Data
(63) Continuation-in-part of application No. 18/226,269, filed on Jul. 26, 2023.

(30) Foreign Application Priority Data
Apr. 10, 2023 (TW) 112113323
Nov. 20, 2023 (TW) 112144700

(51) Int. Cl. C23C 16/44; C09D 5/08; C09D 5/16; C09D 7/20; C09D 7/63; C09D 7/65; C09D 183/04; C23C 16/18; C23C 16/455

(52) U.S. Cl. CPC C23C 16/4404; C09D 5/08; C09D 5/1675; C09D 7/20; C09D 7/63; C09D 7/65; C09D 183/04; C23C 16/18; C23C 16/45544

(57) ABSTRACT

Disclosed is an anti-deposition object with a main structure and a fluorine coating layer, the fluorine coating layer covers at least one surface of the main structure, the anti-deposition object contacts with a substance in an environment, the fluorine coating layer has a water droplet contact angle with the substance higher than that of the surface of the main structure, the fluorine coating layer has a hardness similar to or higher than that of the surface of the main structure, and the fluorine coating layer has a roughness lower than that of the surface of the main structure.

### CROSS-REFERENCE TO RELATED APPLICATION

This application claims the benefit of priority from, and is a continuation-in-part application of U.S. patent application Ser. No. 18/226,269, filed on Jul. 26, 2023, entitled “ANTI-DEPOSITION OBJECT FOR USE IN VACUUM ENVIRONMENT”, which claims the benefit of priority of Taiwan Patent Application No. 112113323, filed on Apr. 10, 2023. In addition, this application also claims priority from Taiwan Patent Application No. 112113323, filed on Apr. 10, 2023; and claims priority from Taiwan Patent Application No. 112144700, filed on Nov. 20, 2023, each of which is hereby incorporated herein by reference in its entireties.

### BACKGROUND OF THE DISCLOSURE

### 1. Field of Disclosure

The disclosure relates to an object, and more particularly to an anti-deposition object.

### 2. Related Art

In recent years, due to the continuous vigorous development of semiconductor technology, technological products have made great progress. In the manufacturing process of semiconductor chips, the chip is usually placed in a manufacturing process equipment for related process operations, and a vacuum pump is used to extract the air or gas in the manufacturing process equipment to keep the manufacturing process equipment in a negative pressure state, that is, in a certain degree of vacuum. However, in the semiconductor manufacturing process, manufacturing process substances such as process gases or process exhaust gases could be easily deposited or accumulated in the fluid channel, which leads to shorter and shorter maintenance cycles to affect manufacturing costs and schedules. Besides, since the air contains many dust particles of different sizes or water vapor with different degrees of contamination, accumulation of dust, scale or stain can easily occur on any object that comes into contact with the air, such as common ceramics, glass or other structures or materials, so they require fairly frequent cleaning, maintenance, or replacement. Similarly, there are many organisms, microorganisms or substances in seawater or freshwater, so objects that often come into contact with seawater, such as common ships, are also prone to various deposition (or adhesion) phenomena.

### SUMMARY OF THE DISCLOSURE

In view of the above, one object of the disclosure is to provide an anti-deposition object to solve the above-mentioned problems in the prior art.

In order to achieve the aforementioned object, the disclosure provides an anti-deposition object comprising: a main structure with at least one surface; and a fluorine coating layer covering the surface of the main structure, wherein the anti-deposition object contacts with a substance in an environment, the fluorine coating layer has a water droplet contact angle with the substance higher than that of the surface of the main structure, the fluorine coating layer has a hardness similar to or higher than that of the surface of the main structure, and the fluorine coating layer has a roughness lower than that of the surface of the main structure.

In order to enable the examiner to have a further understanding and recognition of the technical features of the disclosure and the technical efficacies that could be achieved, preferred embodiments in conjunction with detailed explanation are provided as follows.

### BRIEF DESCRIPTION OF THE DRAWINGS

FIG. 1 is a schematic diagram of a partial structure of an anti-deposition object according to the disclosure.

FIG. 2 is a schematic diagram of application of the anti-deposition object of the disclosure to a manufacturing process equipment.

FIG. 3 is a cross-sectional structural view of a first implementation example of the anti-deposition object according to the disclosure.

FIG. 4 is a cross-sectional structural view of a second implementation example of the anti-deposition object according to the disclosure.

FIG. 5 is a cross-sectional structural view of a third implementation example of the anti-deposition object according to the disclosure.

FIG. 6 is a perspective structural view of a fourth implementation example of the anti-deposition object according to the disclosure.

### DETAILED DESCRIPTION OF THE DISCLOSURE

In order to understand the technical features, content and advantages of the disclosure and its achievable efficacies, the disclosure is described below in detail in conjunction with the figures, and in the form of embodiments, the figures used herein are only for a purpose of schematically supplementing the specification, and may not be true proportions and precise configurations after implementation of the disclosure; and therefore, relationship between the proportions and configurations of the attached figures should not be interpreted to limit the scope of the claims of the disclosure in actual implementation. In addition, in order to facilitate understanding, the same elements in the following embodiments are indicated by the same referenced numbers. And the size and proportions of the components shown in the drawings are for the purpose of explaining the components and their structures only and are not intending to be limiting.

Unless otherwise noted, all terms used in the whole descriptions and claims shall have their common meaning in the related field in the descriptions disclosed herein and in other special descriptions. Some terms used to describe in the present disclosure will be defined below or in other parts of the descriptions as an extra guidance for those skilled in the art to understand the descriptions of the present disclosure.

The terms such as “first”, “second”, “third” and “fourth” used in the descriptions are not indicating an order or sequence, and are not intending to limit the scope of the present disclosure. They are used only for differentiation of components or operations described by the same terms.

Moreover, the terms “comprising”, “including”, “having”, and “with” used in the descriptions are all open terms and have the meaning of “comprising but not limited to”.

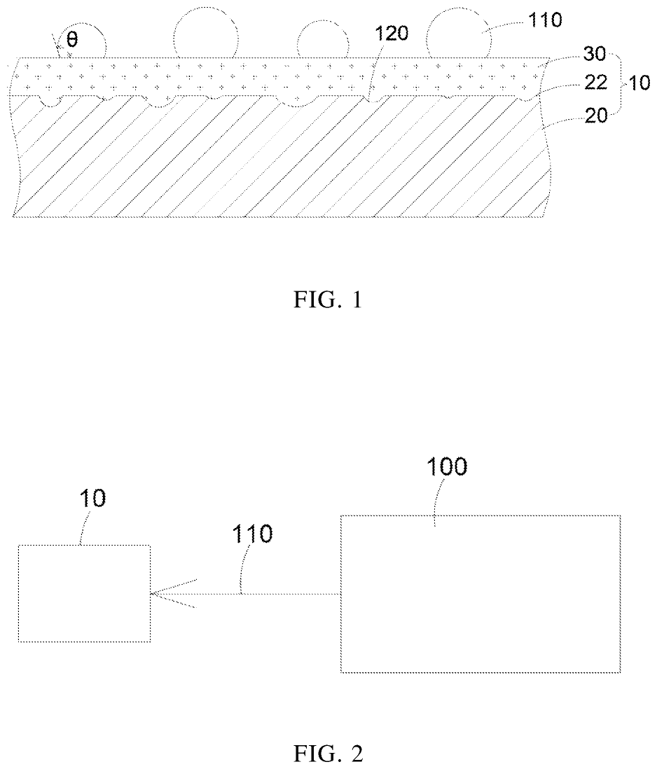

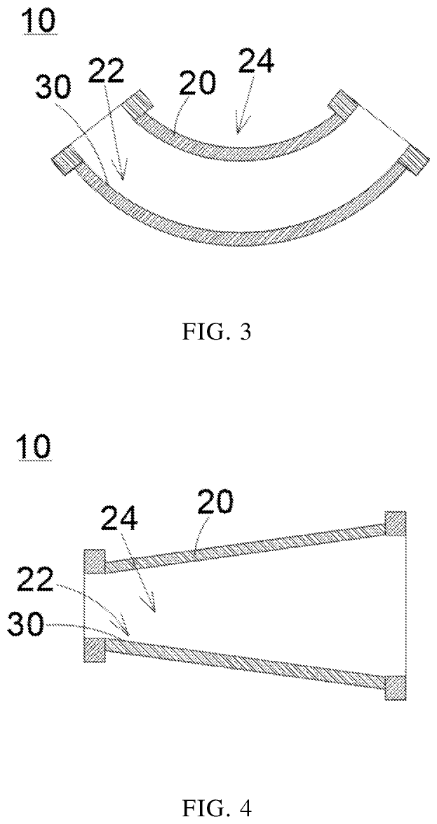

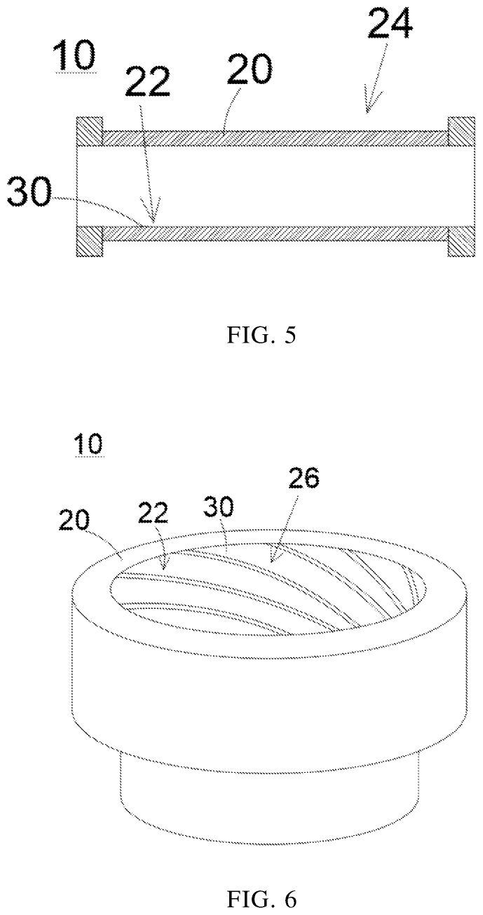

Please refer to FIG. 1 to FIG. 6. FIG. 1 is a schematic diagram of a partial structure of an anti-deposition object according to the disclosure. FIG. 2 is a schematic diagram of application of the anti-deposition object of the disclosure to a manufacturing process equipment. FIG. 3 is a cross-sectional structural view of a first implementation example of the anti-deposition object according to the disclosure. FIG. 4 is a cross-sectional structural view of a second implementation example of the anti-deposition object according to the disclosure. FIG. 5 is a cross-sectional structural view of a third implementation example of the anti-deposition object according to the disclosure. FIG. 6 is a perspective structural view of a fourth implementation example of the anti-deposition object according to the disclosure.

An anti-deposition object of the disclosure has a fluorine coating layer covering a surface of a main structure, thereby preventing the surface from being deposited caused by contacting with substances in an environment, achieving self-cleaning and easy-to-clean effects, and avoiding scratches caused by impact with substances in the environment. The environment is, for example, a vacuum environment, a gas phase environment, a liquid phase environment, or a gas-liquid mixed environment. In other words, the anti-deposition object of the disclosure is not limited to applications in a vacuum environment, but could also be applied in non-vacuum environments. As long as an anti-deposition effect could be provided, any environment falls within the scope of protection claimed by the disclosure.

As shown in FIGS. 1 to 6, an anti-deposition object 10 of the disclosure comprises a main structure 20 and a fluorine coating layer 30, and the fluorine coating layer 30 covers the main structure 20. The anti-deposition object 10 of the disclosure is, for example, applied in a vacuum environment or a non-vacuum environment. Taking a vacuum environment as an example, the anti-deposition object 10, for example, contacts with a substance 110, or called a manufacturing process substance, used or discharged during a manufacturing process performed by a manufacturing process equipment 100 in the vacuum environment, wherein the vacuum environment is not limited to a specific vacuum degree, it depends on requirements of the manufacturing process equipment 100. The above-mentioned environment could also be a non-vacuum environment, such as a gas phase environment, a liquid phase environment, or a gas-liquid mixed environment, and the anti-deposition object 10 of the disclosure contacts the substance 110 in the environment. The fluorine coating layer 30 covers at least one surface 22 of the main structure 20. The fluorine coating layer 30 of the anti-deposition object 10 of the disclosure could, for example, cover all or part of the surfaces of the main structure 20, such as the surface 22 of a part 24 of the main structure 20. Wherein the part 24 could be a position where deposition of manufacturing process substances usually occurs, for example, non-planar places such as bends or slopes, and for example but not limited to inner wall surfaces. Therefore, in the disclosure, the part 24 is, for example, a curved part (as shown in FIG. 3) or an inclined part (as shown in FIG. 4) of the main structure 20, but the disclosure is not limited thereto. The fluorine coating layer 30 of the disclosure could also cover a planar part (as shown in FIG. 5) of the main structure 20. In addition, the main structure 20 of the anti-deposition object 10 of the disclosure is, for example, an outlet pipe (as shown in FIGS. 3 to 5) of the manufacturing process equipment 100 or a pipe fitting (as shown in FIGS. 3 to 5) or a component (a Holweck pump part with a helical diversion groove 26 shown in FIG. 6) of a peripheral equipment (such as a vacuum air pump) of the manufacturing process equipment 100. Although the above-mentioned various forms of the main structure 20 of the anti-deposition object 10 are listed, the disclosure is not limited thereto, all forms of objects that could be applied in a vacuum environment belong to a scope of protection claimed by the disclosure. For example, the anti-deposition object 10 and the main structure 20 thereof of the disclosure could also be, for example, cavities or parts of a vacuum pump, such as a rotor blade and/or a stator blade of a turbomolecular vacuum pump (TMP). For example, the anti-deposition object 10 and the main structure 20 thereof of the disclosure could also be, for example, cavities or parts of a valve structure. In short, the disclosure could optionally form the fluorine coating layer 30 on all surfaces of objects that may contact with the substance 110.

One of the features of the anti-deposition object 10 of the disclosure lies in the surface 22 of the main structure 20 being covered by the fluorine coating layer 30, so the fluorine coating layer 30 could replace the surface 22 of the main structure 20 to contact with the substance 110 used or discharged during the manufacturing process performed by the manufacturing process equipment 100. Wherein the fluorine coating layer 30, for example, could cover the surface 22 of the main structure 20 by coating methods, wherein the coating methods are, but not limited to spray coating, brush coating, dip coating or wipe coating, for example. Wherein the disclosure could, for example, directly coat the liquid (fluid state) fluorine coating layer 30 on the surface 22 of the main structure 20, or coat the liquid fluorine coating layer 30 on the surface 22 of the main structure 20 after the surface 22 of the main structure 20 is roughened to increase a surface roughness. Roughening treatment could be, for example but not limited to, pickling, laser or sandblasting, so as to form rough surfaces of rough structures 120 with more grooves or notches on the surface 22 of the main structure 20 in order to increase an adherence between the fluorine coating layer 30 and the surface 22 of the main structure 20. The disclosure is not limited to specific pickling, laser or sandblasting means, that is, no matter what kind of technical means is used for roughening treatment, as long as a surface roughness of the main structure 20 could be increased, it belongs to a scope of protection claimed by the disclosure, so it will not be described in detail herein.

In addition, since air carries many dust particles or water vapor, and there are many organisms, microorganisms or substances in seawater or freshwater, various deposition (or adhesion) phenomena could easily occur on objects that come into contact with air, seawater or freshwater, so it requires fairly frequent cleaning, maintenance or replacement. As shown in FIG. 1, the anti-deposition object 10 of the disclosure has the fluorine coating layer 30 covering a surface 22 of the main structure 20, thereby preventing various deposition phenomena caused by the surface 22 coming into contact with substances in an environment, achieving self-cleaning and easy-to-clean effects, and avoiding scratches caused by impact with substances in the environment. For example, the environment is a vacuum environment, a gas phase environment, a liquid phase environment, or a gas-liquid mixed environment, but is not limited thereto. The substances depend on the environment in which the anti-deposition object 10 is located, so they will not be described herein. For example, the main structure 20 of the anti-deposition object 10 of the disclosure is, for example, a main structure, part, component or material of an indoor or outdoor building structure, power generation equipment or means of transportation, thereby in addition to exerting original functions and efficacies of the main structure 20, the fluorine coating layer 30 is further capable of providing additional functions and efficacies, such as anti-deposition or anti-scratch effects, thereby improving cleaning, repair or maintenance cycles. Taking a building structure as an example, the main structure 20 of the anti-deposition object 10 of the disclosure is, for example, a main structure, part, component or material of an indoor or outdoor building structure such as structural material, decorative material and special material, but is not limited thereto. For example, the structural material of the building structure is, but not limited to, a main structure, part, component or material of an indoor or outdoor building structure such as metal, wood, stone, cement, concrete, masonry, ceramic, glass, engineering plastic, composite material or combinations thereof. Wherein, the glass is, for example, indoor (such as bathroom) or outdoor (such as window) glass, thereby preventing scale or dust from sticking, for example. The decorative material for building structures comprises, but is not limited to, a main structure, part, component or material of an indoor or outdoor building structure such as coating, paint, board, ceramic tile, glass, composite material or combinations thereof. The special material for building structures is, for example, but not limited to, a main structure, part, component or material of an indoor or outdoor building structure that has functions such as waterproof, moisture-proof, anti-corrosion, fire-proof, flame-retardant, sound insulation, heat insulation, thermal insulation, sealing or combinations thereof. The composite material is, for example, but not limited to, an emerging composite material used as a composite material for construction that is gradually being widely used in the field of building interiors and furniture such as foamed plastic (such as polyethylene, PET) sandwich panel, composite panel that combines wood core and light hardwood surface material (such as balsa wood) or aluminum composite panel (such as aluminum-plastic panel). Thereby the materials are capable of exerting their efficacies. For example, the composite material used in buildings is capable of reducing an overall weight of a building and effectively improving an earthquake resistance level of the building. Taking power generation equipment as an example, the main structure 20 of the anti-deposition object 10 of the disclosure could be, for example, a main structure, part, component or material of power generation equipment such as wind power generation equipment, hydropower generation equipment, wave power generation equipment or solar power generation equipment. For example, the main structure 20 is, but not limited to, a blade of power generation equipment. Taking means of transportation as an example, the main structure 20 of the anti-deposition object 10 of the disclosure could be, for example, a main structure, part, component or material of various sea, land and air means of transportation such as ship, vehicle or airplane, wherein the main structure is, for example, but not limited to, a car body, a fuselage or a hull, and the part, component or material is, for example, but not limited to, various members or materials of a ship, a vehicle or an aircraft. For example, if the main structure 20 of the anti-deposition object 10 of the disclosure is a main structure, part, component or material of a ship, the main structure 20 is capable of exerting efficacies of preventing attachment of barnacles or other organisms or microorganisms or preventing seawater corrosion, whether on a water surface or under a water surface. In short, the anti-deposition object 10 of the disclosure is capable of avoiding physical reactions (such as scratches, etc.) or chemical reactions (such as deposition or corrosion, etc.) caused by contacting with various substances in an environment (such as vacuum environment, gas phase environment, liquid phase environment or gas-liquid mixed environment) where the anti-deposition object 10 is located. Although the disclosure tries its best to enumerate possible application examples, the anti-deposition object 10 of the disclosure could be used to replace a main structure, part, component or material of any existing building structure, power generation equipment or means of transportation, so the above-enumerated applications are only examples and are not intended to limit the scope of protection claimed by the disclosure. All modes of the anti-deposition object 10 that could be applied in a vacuum environment, a gas phase environment, a liquid phase environment or a gas-liquid mixed environment belong to the scope of protection claimed by the disclosure.

In the disclosure, after the liquid (fluid state) fluorine coating layer 30 is coated on the surface 22 of the main structure 20, it could optionally be subjected to self-condensation reaction at room temperature for about 1 to 7 days or subjected to self-condensation reaction at 40 degrees Celsius to 60 degrees Celsius for about 1 to 24 hours, that is, the fluorine coating layer 30 is solidified on the surface 22 of the main structure 20 to form the solidified fluorine coating layer 30. A thickness of the fluorine coating layer 30 could range from 1 μm to 3,000 μm, and could be any numerical interval or upper and lower endpoint values in this range, for example, from 10 μm to 300 μm. Physical and chemical properties of the fluorine coating layer 30 are superior to original physical and chemical properties of the surface 22 of the main structure 20. For example, in a vacuum environment, the fluorine coating layer 30 has a water droplet contact angle θ with the substance 110 higher than that of the surface 22 of the main structure 20, that is, the water droplet contact angle θ (range is about 100° to 140°, and could be any numerical interval or upper and lower endpoint values in this range, such as) 106.5° between the fluorine coating layer 30 and the substance 110 is higher than the water droplet contact angle θ (range is approximately 89 to 95 degrees) between the surface 22 of the main structure 20 and the substance 110. In the disclosure, by coating the fluorine coating layer 30 with the high water droplet contact angle θ on vacuum components is capable of preventing the vacuum components from depositing, and further capable of achieving effects of self-cleaning and easy-cleaning. The fluorine coating layer 30 has a hardness similar to or higher than that of the surface 22 of the main structure 20, that is, a hardness of the fluorine coating layer 30 (ranging from about 8H to 9H, and could be any numerical interval or upper and lower endpoint values in this range) is close to, the same as or higher than a hardness of the surface 22 of the main structure 20 (ranging from about 4H to 6.5H). In the disclosure, by coating the fluorine coating layer 30 with a high hardness on the vacuum components is capable of preventing the vacuum components from being scratched by impact of manufacturing process substances such as particles. An adherence between the fluorine coating layer 30 and the surface 22 of the main structure 20 (cross-cut test range is about 4B to 5B) is higher than a contact force of the substance 110 applied to the fluorine coating layer 30 (for example, external forces or adsorption forces impacting the fluorine coating layer 30 when the substance 110 is discharged), thereby the fluorine coating layer 30 of the disclosure has excellent adherence to the main structure 20 to avoid peeling off during the manufacturing process. Compared with the surface 22 of the main structure 20, the fluorine coating layer 30 has a higher resistance to acid corrosion and plasma etching, thereby the fluorine coating layer 30 of the disclosure is capable of protecting the vacuum components from acid corrosion and free radicals erosion. The fluorine coating layer 30 has a roughness lower than that of the surface 22 of the main structure 20, that is, a roughness (about 0.2) of the fluorine coating layer 30 is lower than a roughness of the surface 22 of the main structure 20, even the fluorine coating layer 30 could further provide an effect of filling or infiltrating the rough structures 120 such as grooves or notches on the surface 22 of the main structure 20 to achieve an efficacy of planarization. In addition, the fluorine coating layer 30 of the disclosure is capable of withstanding relatively high temperatures, an operating temperature range thereof is quite wide, and a temperature tolerance could be as high as about 600 degrees Celsius. An operating temperature range of the fluorine coating layer 30 is, for example, less than or equal to about 600 degrees Celsius, preferably, for example, from about 260 degrees Celsius to 600 degrees Celsius, and could be any numerical interval or upper and lower endpoint values of less than or equal to 600 degrees Celsius. In contrast, conventional water-repellent coatings or anti-fouling coatings usually could not withstand high temperatures. For example, a temperature for using conventional Teflon is lower than 260 degrees Celsius. Not to mention a hardness of conventional water-repellent coatings or anti-fouling coatings is only about 1H to 3H, for example, a hardness of conventional Teflon is 1H to 2H. It could be known from this that conventional water-repellent layers or anti-fouling layers could not withstand high temperature, high vacuum, high corrosion, high impact and high deposition environment when the manufacturing process equipment 100 performs the semiconductor manufacturing process. In other words, the anti-deposition object 10 of the disclosure is capable of saving capital and manpower for frequent maintenance by combining the fluorine coating layer 30 with the main structure 20.

A composition of the fluorine coating layer 30 of the disclosure could be, for example, composed of fluorocarbons accounting for about 0.01 to 20 wt %, alkoxysilanes accounting for about 5 to 50 wt %, catalytic additives accounting for about 0.01 to 20 wt % and solvents accounting for about 10 to 90 wt %. The fluorocarbons are, for example, fluorine-containing monomers or polymers containing 1 to 20 carbon atoms. The fluorocarbons are, for example, fluorine-containing monomers containing from about 3 to about 20 carbon atoms and at least one terminal trifluoromethyl. As an example, the fluorocarbons are selected from, for example, a group consisting of polyfluoroalkyl substances (PFAS), fluorochlorocarbons (CFCs), hydrofluorocarbons (HFCs), fluoropolymers (PTFE) and hydrofluorochlorocarbons (HCFCs). The alkoxysilanes are selected from, for example, a group consisting of alkoxysilane oligomer, alkoxysilane compound, alkoxysilane polymer, alkylsiloxane oligomer, alkylsiloxane compound, alkylsiloxane polymer, amino-alkyl siloxane oligomer, amino-alkyl siloxane compound and amino-alkyl siloxane polymer. The catalytic additives are selected a group consisting of metals, metal oxides, phosphates and carboxylates of platinum, titanium, tin, zinc, aluminum, silver, calcium, magnesium, potassium, sodium, nickel, chromium, molybdenum, vanadium, copper, iron, cobalt, germanium, hafnium, lanthanum, lead, ruthenium, tantalum, tungsten and zirconium. For example, the catalytic additives are selected from a group consisting of silicon oxides, aluminum oxides, titanium oxides, iron oxides, magnesium oxides, molybdenum oxides, calcium oxides and calcium chlorides, and are, for example, nano-size. But the disclosure is not limited thereto. Micronano-sized or even micron-sized catalytic additives or components belong to a scope of protection claimed by the disclosure. The solvents are, for example, alcohols such as ethanol, propanol, or butanol. However, the disclosure is not limited thereto, the solvents of the disclosure could be selected from a group consisting of alcohols, ketones, esters, fluoroalcohols, fluoroethers and ethers. The alkoxysilanes of the disclosure have reactive functional groups, and the reactive functional groups carry out a self-condensation reaction at room temperature for 1 to 7 days (for example, 7 days) or carry out a self-condensation reaction at a temperature of 40 to 60 degrees Celsius for 1 to 24 hours (for example, 24 hours). Wherein the above-mentioned reactive functional groups are, for example, hydrosilated reactive functional groups (such as hydrogen atoms of alkenyl, acryl bonded to silicon atoms), condensation reactive functional groups (such as hydroxyl, alkoxy, acyloxy) or peroxide hardening reactive functional groups (such as alkyl, alkenyl, acryl, hydroxyl). In addition, in a feasible implementation mode, a composition of the fluorine coating layer 30 of the disclosure could also be, for example, organic/inorganic macromolecular copolymers composed of fluorine, nano-titanium, silicon and silicon elastomer. Since a person having ordinary skill in the art to which the disclosure pertains should know how to select and modulate the anti-deposition object 10 of the fluorine coating layer 30 having the efficacies of the disclosure based on the foregoing contents of the disclosure, so no further details are given herein. In addition, a degree of fluorination of the fluorine coating layer 30 of the anti-deposition object 10 of the disclosure could be correspondingly increased according to an environment (for example, an ozone water-containing environment such as a vapor ozone strip (VOS) process or its applications) in which the anti-deposition object 10 is located, such as adding per/polyfluoroalkyl substances (PFAS) (for example, perfluorooctanoic acid (PFOA) or perfluorooctane sulfonic acid (PFOS)), polytetrafluoroethylene (PTFE) or fluorinated ethylene propylene (FEP). The disclosure is capable of enhancing a stability of the anti-deposition object 10 to ozone water in an environment by increasing a degree of fluorination of the anti-deposition object 10 in various application modes.

A surface hardness testing method of the disclosure uses a hardness pencil to test a surface hardness of the fluorine coating layer 30. For example, load a hardness pencil (Mitsubishi standard pencil) on a trolley with a fixed load at an angle of 45 degrees, and then push the trolley by hand to slide over a surface of the fluorine coating layer 30 of the anti-deposition object 10 to confirm a surface hardness when scratched by a pencil. In the anti-deposition object 10 of the disclosure, all surface hardness test results of the fluorine coating layer 30 covering the surface 22 of the main structure 20 are between 8H load 1 Kg and 9H load 500 g.

The cross-cut test of the disclosure is performed according to ASTM D3359 method B (cross-cut method). The test method uses a cross-cut knife to draw 10×10 (100 pieces) 1 mm×1 mm small grid lines on a surface of a test sample, each drawn line should reach a bottom layer of the fluorine coating layer 30 of the anti-sediment object 10; use a brush to clean debris in a test area; use a standard adhesive tape (3M tape No. 600) or an equivalent adhesive tape to stick to the tested small grid lines, use an eraser to rub the tape vigorously to increase a contact area and a strength between the tape and the tested area, grab one end of the tape with a hand, and quickly tear off the tape at an angle of 180 degrees within 1.5 minutes plus or minus 30 seconds and observe a state of peeling off of the fluorine coating layer 30. In the anti-deposition object 10 of the disclosure, all results of the cross-cut test of the fluorine coating layer 30 of the disclosure coated on the surface 22 of the main structure 20 are between 5B (cut edges are completely smooth, and grid edges do not have any peeling off) and 4B (small flakes at intersections of cuts, and actual damage ≤5% inside grid areas). It could be known from the results that an adhesion (adherence) of the fluorine coating layer 30 of the disclosure to the surface 22 of the main structure 20 is quite high.

An acid corrosion resistance test experiment of the disclosure uses 0.05 mL of 5% HCl (hydrochloric acid) to drop on a test sample, let it stand for 24 hours, and wait for the HCl solution to volatilize. During the volatilization process, a concentration of the HCl area will rise, and an effect of diffusion corrosion will increase. After 24 hours of observation, a diffusion area is corroded. According to the test results, a corrosion area (mm²) of the surface 22 of the main structure 20 without coating the fluorine coating layer 30 is about 45.13 mm², but a corrosion area (mm²) of the surface 22 of the main structure 20 coated with the fluorine coating layer 30 is only about 19.4 mm².

In addition, the disclosure has also undergone a plasma etching test, results show that under the same etching conditions (CHF₃:Ar is 1:1, 60 minutes, a rate of etching oxides is 750 nm/30 min), the fluorine coating layer 30 of the disclosure reliably has a resistance to plasma etching better than that of the surface 22 of the main structure 20 (made of anodized aluminum). As for a thermal stability test (thermogravimetric analyzer, TGA test), under a test environment of heating rate being 5 degrees Celsius/min and test atmosphere being N₂, a weight of the fluorine coating layer 30 of the disclosure shows a steady and slow decline within a test temperature range (600 degrees Celsius), and there is no sudden weight change, showing that cracking does not occur in the fluorine coating layer 30 of the anti-deposition object 10 of the disclosure.

The manufacturing process performed by the manufacturing process equipment 100 is, for example, a semiconductor manufacturing process. For example, the manufacturing process performed by the manufacturing process equipment 100 is an atomic layer deposition (ALD) manufacturing process, and the manufacturing process substance 110 is titanium tetrachloride (TiCl₄), wherein the main structure 20 of the anti-deposition object 10 is, for example, a fluid delivery pipe, but not limited thereto. For example, the manufacturing process performed by the manufacturing process equipment 100 is a metalorganic chemical vapor deposition (MOCVD) manufacturing process, and the manufacturing process substance 110 is a process gas or a process exhaust gas, wherein the main structure 20 of the anti-deposition object 10 is, for example, an outlet pipe of a vacuum air pump, but not limited thereto. For example, the manufacturing process performed by the manufacturing process equipment 100 is an Al-pad manufacturing process, and the manufacturing process substance 110 is a process gas reactant or a process exhaust gas, such as selected from a group consisting of N₂, O₂, Ar, SF₆, He, HBr, CF₄, CH₄, Cl₂, BCl₃ and CHF₃, wherein the main structure 20 of the anti-sedimentation object 10 is, for example, a pump part and an outlet pipe with a helical diversion groove, but not limited thereto. The anti-deposition object 10 of the disclosure has been tested in practice and has excellent effects in the above-mentioned manufacturing processes. For example, in the Al-pad manufacturing process, the anti-deposition object 10 of the disclosure is capable of extending about 20% of a maintenance cycle, so is capable of reducing capital and manpower for frequent maintenance.

In summary, the anti-deposition object of the disclosure has the following advantages:

(1) By coating the fluorine coating layer with a high hardness on vacuum components is capable of preventing the vacuum components from being scratched by impact of manufacturing process substances such as particles.

(2) By coating the fluorine coating layer with a high water droplet contact angle on the vacuum components is capable of preventing the vacuum components from depositing, and further capable of achieving effects of self-cleaning and easy-cleaning.

(3) The fluorine coating layer has excellent adherence to the main structure to avoid peeling off during the manufacturing process.

(4) By providing the anti-deposition object with the fluorine coating layer is capable of saving capital and manpower for frequent maintenance.

(5) By coating main structures, parts or components of building structures, power generation equipment or means of transportation with the fluorine coating layer with a high-hardness is capable of preventing deposition phenomena caused by contacting with substances in an environment, achieving self-cleaning and easy-to-clean effects, and avoiding scratches caused by impact with substances in the environment.

Note that the specification relating to the above embodiments should be construed as exemplary rather than as limitative of the present disclosure, with many variations and modifications being readily attainable by a person of average skill in the art without departing from the spirit or scope thereof as defined by the appended claims and their legal equivalents.

What is claimed is:

1. An anti-deposition object at least comprising:
a main structure with at least one surface; and
a fluorine coating layer covering the surface of the main structure, wherein the anti-deposition object contacts with a substance in an environment, the fluorine coating layer has a water droplet contact angle with the substance higher than that of the surface of the main structure, the fluorine coating layer has a hardness similar to or higher than that of the surface of the main structure, and the fluorine coating layer has a roughness lower than that of the surface of the main structure.

2. The anti-deposition object as claimed in claim 1, wherein the main structure is an outlet pipe fitting of a manufacturing process equipment or a pipe fitting or a component of a peripheral equipment of the manufacturing process equipment.

3. The anti-deposition object as claimed in claim 1, wherein the fluorine coating layer is located on the surface of a part of the main structure, and the part is an inclined part, a planar part or a curved part of the main structure.

4. The anti-deposition object as claimed in claim 1, wherein the fluorine coating layer has an acid corrosion resistance and a plasma etching resistance higher than those of the surface of the main structure.

5. The anti-deposition object as claimed in claim 1, wherein the surface of the main structure is roughened to form rough surfaces with rough structures to increase a surface roughness.

6. The anti-deposition object as claimed in claim 1, wherein the surface of the main structure is roughened by pickling, laser or sandblasting to increase a surface roughness.

7. The anti-deposition object as claimed in claim 1, wherein a composition of the fluorine coating layer is composed of fluorocarbons accounting for 0.01 to 20 wt %, alkoxysilanes accounting for 5 to 50 wt %, catalytic additives accounting for 0.01 to 20 wt % and solvents accounting for 10 to 90 wt %.

8. The anti-deposition object as claimed in claim 7, wherein the fluorocarbons are selected from a group consisting of polyfluoroalkyl substances (PFAS), fluorochlorocarbons (CFCs), hydrofluorocarbons (HFCs), polytetrafluoroethylene (PTFE) and fluorinated ethylene propylene (FEP).

9. The anti-deposition object as claimed in claim 7, wherein the fluorocarbons are fluorine-containing monomers or polymers containing 1 to 20 carbon atoms.

10. The anti-deposition object as claimed in claim 7, wherein the alkoxysilanes are selected from a group consisting of alkoxysilane oligomer, alkoxysilane compound, alkoxysilane polymer, alkylsiloxane oligomer, alkylsiloxane compound, alkylsiloxane polymer, amino-alkyl siloxane oligomer, amino-alkyl siloxane compound and amino-alkyl siloxane polymer.

11. The anti-deposition object as claimed in claim 7, wherein the catalytic additives are selected a group consisting of metals, metal oxides, phosphates and carboxylates of platinum, titanium, tin, zinc, aluminum, silver, calcium, magnesium, potassium, sodium, nickel, chromium, molybdenum, vanadium, copper, iron, cobalt, germanium, hafnium, lanthanum, lead, ruthenium, tantalum, tungsten and zirconium.

12. The anti-deposition object as claimed in claim 7, wherein the solvents are selected from a group consisting of alcohols, ketones, esters, fluoroalcohols, fluoroethers and ethers.

13. The anti-deposition object as claimed in claim 7, wherein the alkoxysilanes have reactive functional groups, and the reactive functional groups carry out a self-condensation reaction at room temperature for 1 to 7 days or carry out a self-condensation reaction at a temperature of 40 to 60 degrees Celsius for 1 to 24 hours.

14. The anti-deposition object as claimed in claim 1, wherein the environment is a vacuum environment, the substance is a manufacturing process substance, the anti-deposition object contacts with the manufacturing process substance used or discharged during a manufacturing process performed by a manufacturing process equipment in the vacuum environment, the manufacturing process performed by the manufacturing process equipment is an atomic layer deposition (ALD) manufacturing process, and the manufacturing process substance is titanium tetrachloride (TiCl₄).

15. The anti-deposition object as claimed in claim 1, wherein the environment is a vacuum environment, the substance is a manufacturing process substance, the anti-deposition object contacts with the manufacturing process substance used or discharged during a manufacturing process performed by a manufacturing process equipment in the vacuum environment, the manufacturing process performed by the manufacturing process equipment is a metalorganic chemical vapor deposition (MOCVD) manufacturing process, and the manufacturing process substance is a process gas or a process exhaust gas.

16. The anti-deposition object as claimed in claim 1, wherein the environment is a vacuum environment, the substance is a manufacturing process substance, the anti-deposition object contacts with the manufacturing process substance used or discharged during a manufacturing process performed by a manufacturing process equipment in the vacuum environment, the manufacturing process performed by the manufacturing process equipment is an Al-pad manufacturing process, and the manufacturing process substance is a process gas reactant or a process exhaust gas.

17. The anti-deposition object as claimed in claim 1, wherein the water droplet contact angle of the fluorine coating layer ranges from 100° to 120°.

18. The anti-deposition object as claimed in claim 1, wherein a temperature tolerance of the fluorine coating layer reaches 600 degrees Celsius.

19. The anti-deposition object as claimed in claim 1, wherein the hardness of the fluorine coating layer ranges from 8H to 9H.

20. The anti-deposition object as claimed in claim 1, wherein an adhesion between the fluorine coating layer and the surface of the main structure ranges from 4B to 5B in a cross-cut test.

21. The anti-deposition object as claimed in claim 1, wherein the environment is a vacuum environment, a gas phase environment, a liquid phase environment or a gas-liquid mixed environment.

22. The anti-deposition object as claimed in claim 1, wherein the main structure is a main structure, a part, a component or a material of building structures, power generation equipment or means of transportation.

23. The anti-deposition object as claimed in claim 1, wherein the environment is an ozone water-containing environment, and the fluorine coating layer increases a degree of fluorination correspondingly according to the ozone water-containing environment to enhance a stability to ozone water in the ozone water-containing environment.
